(19) United States
(12) Patent Application Publication
(10) Pub. No.: US 2007/0158734 A1
(43) Pub. Date: Jul. 12, 2007

(54) Electronic device with a multi-gated electrode structure and a process for forming the electronic device

(75) Inventor: Gowrishankar L. Chindalore, Austin, TX (US)

Correspondence Address: LARSON NEWMAN ABEL POLANSKY & WHITE, LLP, 5914 WEST COURTYARD DRIVE, SUITE 200, AUSTIN, TX, 78730, US

(73) Assignee: Freescale Semiconductor, Inc., Austin, TX (US)

(21) Appl. No.: 11/330,416

(22) Filed: Jan. 9, 2006

(51) Int. Cl. H01L 29/788

(52) U.S. Cl. 257/315

(57) ABSTRACT

An electronic device including a multi-gate electrode structure overlying the channel region further comprising a first and second gate electrode spaced apart from each other by a layer, and a process for forming the electronic device is disclosed. The multi-gate electrode structure can have a sidewall spacer structure having first and second portions. The first and second gate electrodes can have different conductivity types. The electronic device can also include a first gate electrode of a first conductivity type overlying the channel region, a second gate electrode of a second conductivity type lying between the first gate electrode and the channel region, and a first layer capable of storing charge lying between the first gate electrode and the substrate.

### BACKGROUND

1. Field of the Disclosure

The present disclosure relates to electronic devices, more particularly, to multi-gate electronic devices and processes for forming them.

2. Description of the Related Art

Floating gate non-volatile memory (FG NVM) devices built with multi-gate architecture having separate control and select gates can be subject to read-disturb during the read operation. One method to alleviate this problem is to counter dope a portion of the channel region, lowering the threshold voltage (“V_{T}”) needed at the control gate, while leaving the V_{T} needed at the select gate unchanged. The selective lowering of the control gate V_{T} relative to the select gate V_{T} by counter doping can help reduce the incidence of read-disturb events without affecting the write function. However, performing a counter-doping implant can be difficult to control precisely and can require additional lithographic steps resulting in additional process complexity.

### BRIEF DESCRIPTION OF THE DRAWINGS

The present disclosure may be better understood, and its numerous features and advantages made apparent to those skilled in the art by referencing the accompanying drawings. The subject of the disclosure is illustrated by way of example and not limitation in the accompanying figures.

FIGS. 1 through 7, and FIGS. 1 and 8 through 13, each illustrate a process flow for an electronic device in accordance with specific embodiments of the present disclosure.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention. The use of the same reference symbols in different drawings indicates similar or identical items.

### DESCRIPTION OF THE PREFERRED EMBODIMENT(S)

A FG NVM device in accordance with a specific embodiment is disclosed that includes a multi-gate electrode structure having gates of opposing conductivity types. The V_{T} shift resulting from pairing gate electrode materials of opposing conductivity type over a common channel region can reduce the external voltage used to turn on the portion of the channel region controlled by one of the gates, i.e. the control gate, without affecting the voltage required to turn off the portion of the channel controlled by another gate, i.e. the select gate.

Specific embodiments of the present disclosure will be better understood with reference to FIGS. 1 through 13.

FIG. 1 includes a cross-sectional view of an illustration of a portion of a workpiece 10 where an electronic device can be formed. In the illustrated embodiment, substrate 12 can include a semiconductor-on-insulator (“SOI”) substrate having a layer 14, a layer 16, a layer 18 and region 110. Layer 14 can be can be a support structure to structurally support overlying layers. Layer 16 can be an insulating layer to electrically insulate at least a portion of layer 18 from layer 14. Layer 18 can be a semiconductor layer including a semiconductor element such as silicon, germanium, another semiconductor element, or any combination thereof. Region 110 can be a field isolation region electrically isolating portions of layer 18 from each other. Layer 18 can have either fully or partially depleted active silicon regions where n-type, p-type, or a combination of n-type and p-type channel regions can be formed. In one embodiment, the channel doping can be in a range of approximately 1E18 to approximately 5E18 atoms per cubic centimeter. In an alternative embodiment, further illustrated in FIG. 8, a portion 112 of the channel can be counter-doped to a level of not more than approximately 1 E18 atoms per cubic centimeter. Layer 18 can have a thickness between approximately 50 and approximately 150 nm.

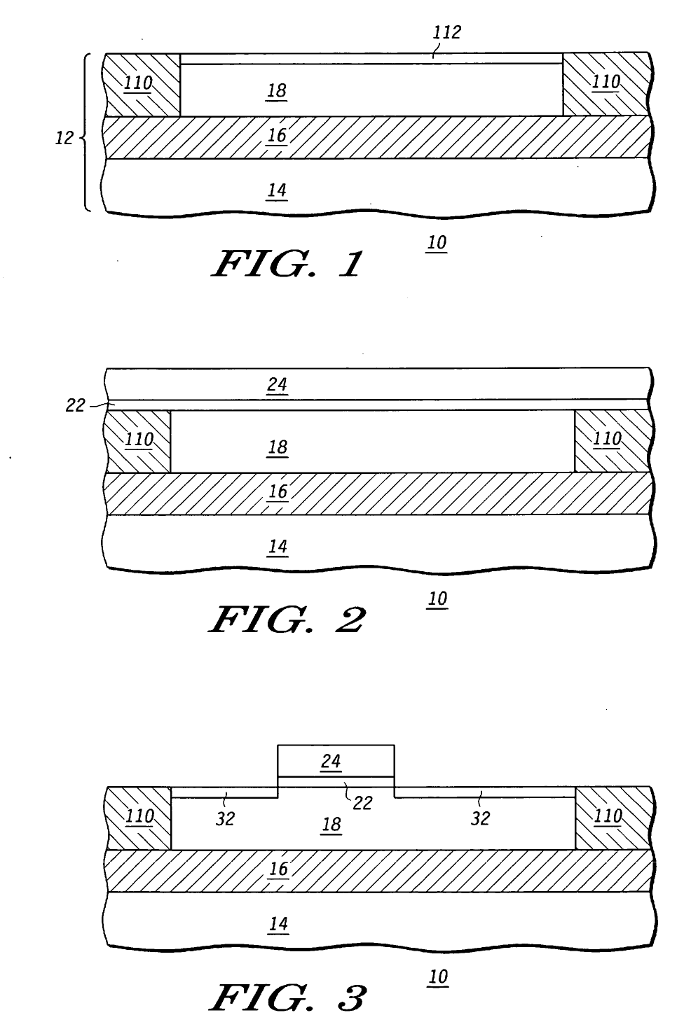

FIG. 2 includes an illustration of the workpiece 10 of FIG. 1 after formation of a layer 22 and a layer 24. Layer 22 can be a dielectric layer and serve as a gate dielectric. Layer 24 can be a conducting layer and serve as a gate electrode. Layer 22 can include a film of silicon dioxide, silicon nitride, silicon oxynitride, a high dielectric constant (“high-k”) material (e.g., dielectric constant greater than 8), or any combination thereof. The high-k material can include HfₐO_{b}N_{c}, HfₐSi_{b}O_{c}, HfₐSi_{b}O_{c}N_{d}, HfₐZr_{b}O_{c}N_{d}, HfₐZr_{b}Si_{c}O_{d}Nₑ, HfₐZr_{b}O_{c}, ZrₐSi_{b}O_{c}, ZrₐSi_{b}O_{c}N_{d}, ZrₐO_{b}, other Hf-containing or Zr-containing dielectric material, a doped version of any of the foregoing (lanthanum doped, niobium doped, etc.), or any combination thereof. As used herein, subscripts on compound materials specified with alphabetic subscripts are intended to represent the non-zero fraction of the atomic species present in that compound, and therefore, the alphabetic subscripts within a compound sum to 1. For example, in the case of HfₐO_{b}N_{c}, the sum of “a,” “b,” and “c” is 1. Layer 22 can have a thickness in a range of approximately 1 to approximately 25 nm. Layer 22 may be thermally grown using an oxidizing or nitridizing ambient, or deposited using a conventional or proprietary chemical vapor deposition (“CVD”) technique, physical vapor deposition (“PVD”) technique, or any combination thereof.

Still referring to FIG. 2, layer 24 can include a material such as amorphous silicon, polysilicon, a nitride, a metal-containing material, another suitable material, and the like, or any combination thereof. In one embodiment, the material of layer 24 can include platinum, palladium, iridium, osmium, ruthenium, rhenium, indium-tin, indium-zinc, aluminum-tin, or any combination thereof. Layer 24 can have a thickness of between approximately 30 and approximately 200 nm and can be grown or deposited using a conventional or proprietary technique, such as a CVD technique, PVD technique, the like, or any combination thereof. In one embodiment, layer 24 is doped with an n-type species such as arsenic or phosphorus.

FIG. 3 includes an illustration of the workpiece 10 of FIG. 2 after removal of portions of layer 22 and layer 24 to form a portion of a multi-gate electrode structure. A patterned layer (not illustrated) can be formed over the workpiece 10 of FIG. 2 by a conventional or proprietary process and exposed portions of layers 22 and 24 can be removed. In the illustrated embodiment, dopant can be introduced into portion 32 of layer 18 as previously described for portion 112. In a particular embodiment, the counter doping level can be reduced because the flat band voltage shift from using an n+ gate electrode over a p-channel, effectively reduces the V_{T} needed at the gate electrode by approximately 1 volt. Reduced counter-doping can help improve performance of the electronic device. Remaining portions of the patterned layer can be removed.

FIG. 4 includes an illustration of the workpiece 10 of FIG. 3 after formation of a layer 42. Layer 42 can act as a floating gate. In one embodiment, layer 42 can comprise a charge storage material embedded within a dielectric material. A portion of layer 42 can be formed by the same or different embodiment as previously described for formation of layer 22. The charge storage material of layer 42 can form one or more regions capable of storing a charge, and can include silicon, a nitride, a metal-containing material, another suitable material capable of storing charge, or any combination thereof. The charge storage material of layer 42 may be undoped, doped during deposition, or doped after deposition. In one embodiment, the charge storage material of layer 42 can be formed from one or more materials whose properties are not significantly adversely affected during a thermal oxidation process. Such a material can include platinum, palladium, iridium, osmium, ruthenium, rhenium, indium-tin, indium-zinc, aluminum-tin, or any combination thereof. Each of such materials, other than platinum and palladium, may form a conductive metal oxide. In a particular embodiment, the charge storage material embedded within layer 42 can comprise a plurality of discontinuous storage elements, each element capable of storing charge. In one embodiment, the charge storage material of layer 42 can be less than approximately 100 nm in thickness.

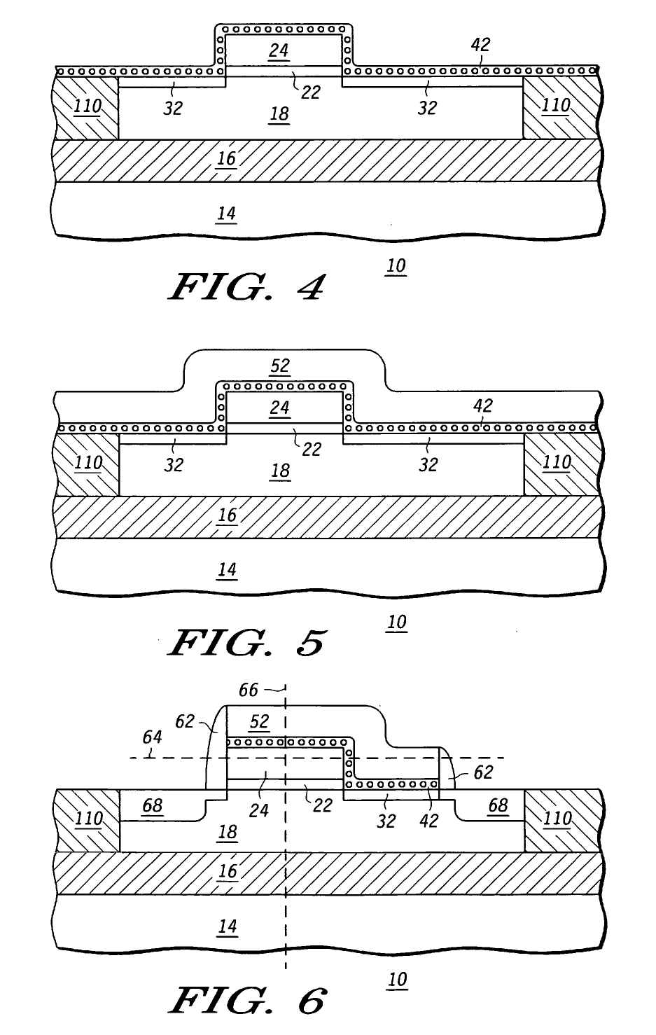

FIG. 5 includes an illustration of the workpiece 10 of FIG. 4 after formation of a layer 52. In one embodiment, layer 52 can be a conducting layer formed by an embodiment as previously described for layer 24. In the illustrated embodiment, the conductivity type in layer 52 is the opposite that of layer 24.

FIG. 6 includes an illustration of the workpiece 10 of FIG. 5 after formation of a multi-gate electrode structure including sidewall spacer structure portions 62. The multi-gate electrode structure includes a gate electrode formed from layer 24 and a gate electrode formed from layer 52 spaced apart from each other by layer 42. An imaginary line 64 is illustrated that is substantially parallel to a major surface (i.e. the top surface) of the substrate 12. Along the imaginary line 64 the region between sidewall spacer portions 62 is substantially filled by portions of layers 24, 42, and 52. An imaginary line 66 is illustrated substantially perpendicular to a major surface of the substrate 12. Along the imaginary line 66, at least a portion of layer 24 lies between layer 52 and the channel region and at least a portion of layer 42 lies between layer 24 and layer 52. Along imaginary line 66, the channel region and layer 52 have dopant of the same conductivity type. In another embodiment, at least a portion of layer 42 and layer 24 lie between the channel region and a portion of layer 52.

The structures of FIG. 6 can be formed by forming a patterned layer over the workpiece 10 (not illustrated) using a conventional or proprietary lithographic process and removing exposed portions of layer 42 and layer 52. Source/Drain (“S/D”) implantation can be performed to form S/D regions 68. In one embodiment, n-doped S/D regions 68 are formed. The patterned layer can be removed. In the illustrated embodiment, a channel region can be formed between sidewall spacer structure portions 62. Sidewall spacer structure portions 62 can be formed by a conventional or proprietary process and can include an oxide, a nitride, an oxynitride, or any combination thereof.

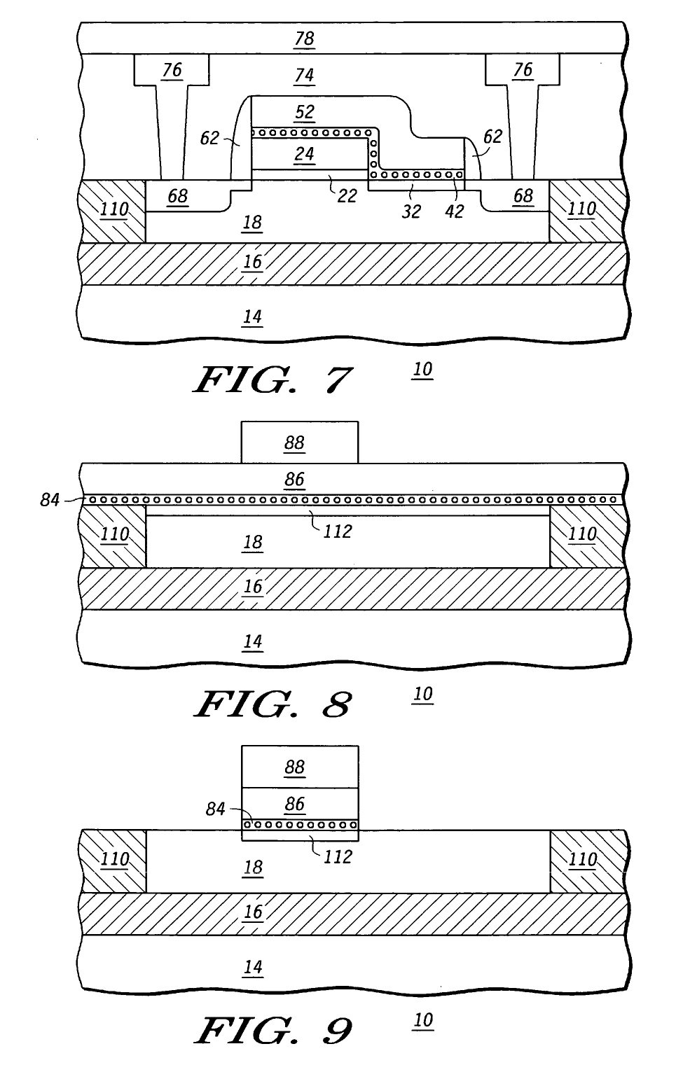

FIG. 7 includes an illustration of a cross-sectional view of a substantially completed electronic device. One or more insulating layers 74, one or more conductive layers 76, and one or more encapsulating layers 78 are formed using one or more conventional or proprietary techniques.

In another embodiment, an alternative structure can be formed in accordance with the present disclosure. FIG. 8 includes an illustration of the workpiece 10 of FIG. 1 after formation of layer 84, layer 86 and patterned layer 88. Layer 84 can serve as a charge storage layer. Layer 86 can be a conductive layer suitable for formation of a gate electrode. Layer 88 can be a patterned layer and can serve to protect portions of the workpiece 10 from subsequent processing, such as etch or implant processes. Layers 84 and 86 can be formed by any embodiment previously described for layer 42 and 52, respectively.

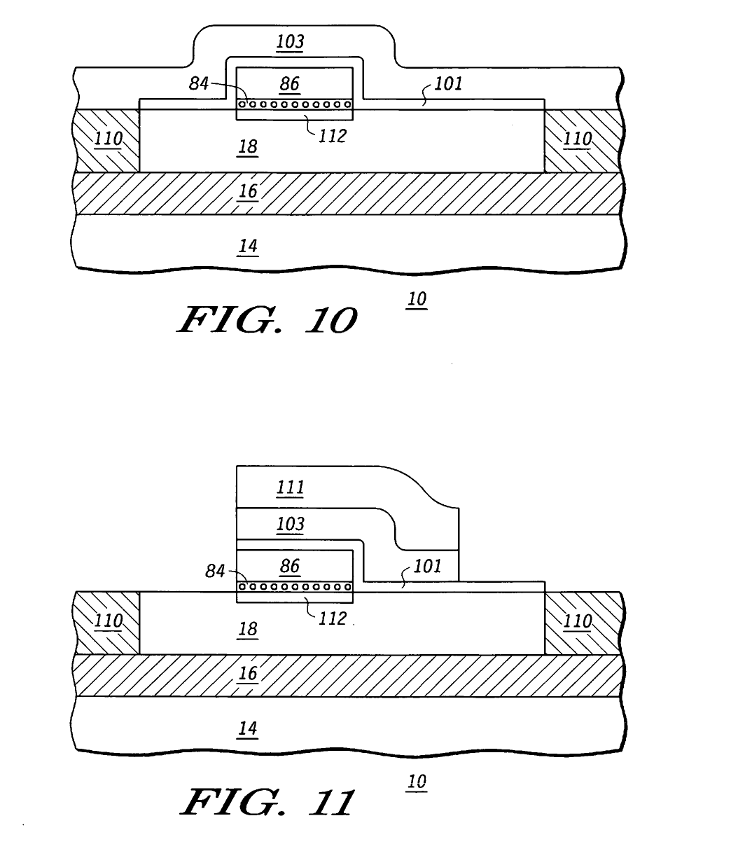

FIG. 9 includes an illustration of the workpiece 10 of FIG. 8 after removal of a portion of layers 84 and 86 to facilitate formation of a portion of a multi-gate electrode structure. Removal of the portion of layers 84 and 86 can expose a portion of the channel region of the multi-gated device being formed. Dopant can be added to the exposed portion of the channel region to adjust the V_{T} required at the select gate of the completed device. In one embodiment, the channel doping can be in a range of approximately 1E18 to approximately 5E18 atoms per cubic centimeter. Patterned layer 88 can be removed from the workpiece 10 using a conventional or proprietary process.

FIG. 10 includes an illustration of the workpiece 10 of FIG. 9 after formation of layers 101 and 103. A portion of layer 101 can serve as a gate dielectric while another portion of layer 101 can serve to separate a gate electrode formed from layer 86 from a gate electrode formed from layer 103. Layers 101 and 103 can be formed by an embodiment previously described for layers 22 and 24 respectively. In the illustrated embodiment, the conductivity type of layer 103 is opposite that of layer 86. For example, layer 103 can be an n-type conductor, and layer 86 can be a p-type conductor.

FIG. 11 includes an illustration of the workpiece of FIG. 10 after removal of a portion of layers 103 and 101 to form a gate from layer 103. The resulting multi-gate electrode structure includes an electrode portion of layers 86 spaced apart from an electrode portion of 103 by at least a portion of layer 101. A portion of layer 84 and a portion of layer 86 lie between the channel region of the multi-gated device being formed and a portion of the electrode formed by layer 103. Patterned layer 111 is formed over the channel region of layer 18 by a conventional or proprietary process to facilitate removal of exposed portions of layers 101 and 103. Dopant can be introduced to a S/D region of the workpiece 10 by a conventional or proprietary process. Dopant concentration can be in a range of approximately 5E18 to approximately 1 E22 atoms per cubic centimeter.

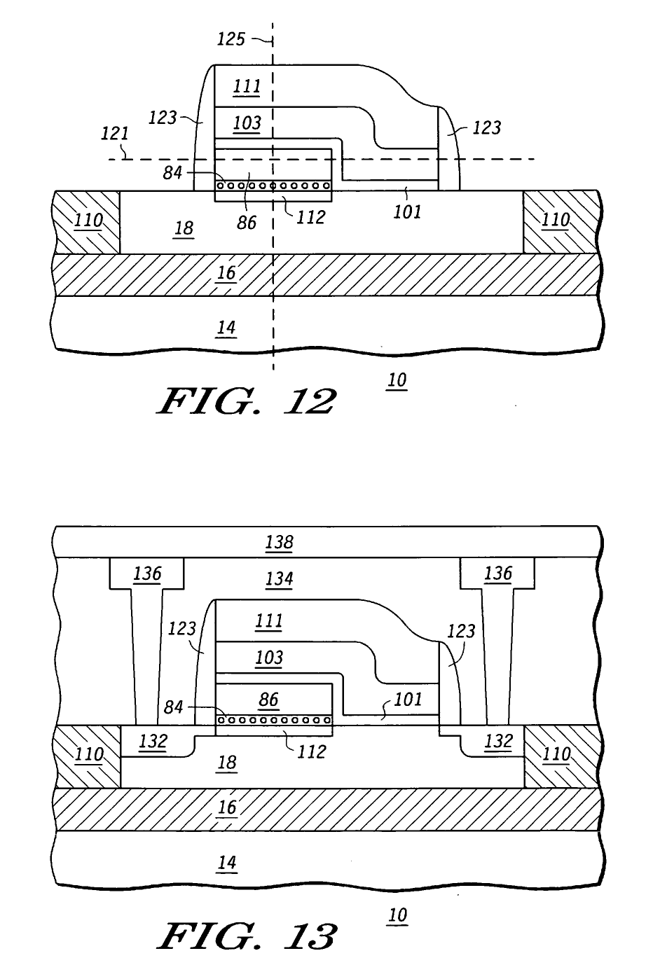

FIG. 12 includes an illustration of the workpiece 10 of FIG. 11 after formation of the multi-gated electrode structure including sidewall spacer structure portions 123. Remaining portions of layers 86, 101, and 103 substantially fill the region between sidewall spacer portions 123 along imaginary line 121. Imaginary line 121 is illustrated substantially parallel to a major surface of the substrate 12. Remaining portions of layer 111 are removed by conventional or proprietary processing. Sidewall spacer structure portions 123 are formed by an embodiment previously described for sidewall spacer structure portions 62. Dopants can be introduced to workpiece 10. A portion of layer 86 lies between layer 103 and the channel region along imaginary line 125. Imaginary line 125 is illustrated substantially perpendicular to a major surface of the substrate 12. Along imaginary line 125, the channel region and layer 103 have dopant of the same conductivity type.

FIG. 13 includes an illustration of a cross-sectional view of a substantially completed electronic device. One or more S/D regions 132 can be formed using a conventional or proprietary process. One or more insulating layers 134, one or more conductive layers 136, and one or more encapsulating layers 138 are formed using one or more conventional or proprietary techniques.

Some terms are defined or clarified as to their intended meaning as they are used within this specification.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Additionally, for clarity purposes and to give a general sense of the scope of the embodiments described herein, the use of the “a” or “an” are employed to describe one or more articles to which “a” or “an” refers. Therefore, the description should be read to include one or at least one whenever “a” or “an” is used, and the singular also includes the plural unless it is clear that the contrary is meant otherwise.

Unless otherwise defined, all technical and scientific terms used herein have the same meaning as commonly understood by one of ordinary skill in the art to which this invention belongs. All publications, patent applications, patents, and other references mentioned herein are incorporated by reference in their entirety. In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the semiconductor and microelectronic arts. Other features and advantages of the invention will be apparent from the following detailed description, and from the claims.

Many different aspects and embodiments of a multi-gated device using the disclosure herein are possible. Some of those aspects and embodiments are described below. After reading this specification, skilled artisans will appreciate that those aspects and embodiments are only illustrative and do not limit the scope of the present invention.

In a first aspect, an electronic device can include a substrate including a channel region. The electronic device can also include a multi-gate electrode structure overlying the channel region, and including a first and second gate electrode spaced apart from each other by at least a first portion of first layer having a first dimension along a first imaginary line, wherein the first imaginary line is substantially parallel to a major surface of the substrate. The first gate electrode of a first conductivity type and having a second dimension along the first imaginary line. The second gate electrode of a second conductivity type and having a third dimension along the first imaginary line, the second conductivity type different from the first conductivity type. The multi-gate electrode structure can also include a first sidewall structure portion separated from a second sidewall structure portion by a fourth dimension along the first imaginary line, wherein the sum of the first, second, and third dimensions are substantially equal to the fourth dimension.

In an embodiment of the first aspect, the first layer includes a dielectric material. In another embodiment, a second portion of the first layer is a gate dielectric between the first gate electrode and the channel region. In a more particular embodiment, the electronic device further includes a gate dielectric between the second gate electrode and the channel region. In an even more particular embodiment, a charge storage material is embedded within the gate dielectric of the first layer. In a still more particular embodiment, the charge storage material further includes a plurality of discontinuous storage elements.

In another still more particular embodiment of the first aspect, the charge storage material includes a floating gate of the electronic device. In another particular embodiment, the second gate electrode lies between the channel region and a portion of the first gate electrode along a second imaginary line perpendicular to a major surface of the substrate. In a more particular embodiment, the channel region has the first conductivity type. In yet another particular embodiment, the electronic device can further include a charge storage material between the second gate electrode and the channel region. In a more particular embodiment, the charge storage material further includes a plurality of discontinuous storage elements. In another more particular embodiment, the charge storage material is a floating gate of the electronic device.

In a second aspect, an electronic device can include a substrate including a channel region and a first gate electrode of a first conductivity type overlying the channel region. The electronic device can also include a second gate electrode of a second conductivity type lying between a portion of the first gate electrode and the channel region, the second conductivity type different from the first conductivity type and a first portion of a layer including a charge storage material lying between the first gate electrode and the substrate.

In an embodiment of the second aspect, a second portion of the layer lies between the first and second gate electrodes. In another embodiment, the channel region further includes a channel region of the first conductivity type. In yet another embodiment, the layer lies between the second gate electrode and the channel region. In still another embodiment, the channel region further includes a channel region of the second conductivity type.

In an third aspect, a process for forming an electronic device can include forming a first gate electrode of a first conductivity type overlying a channel region of a substrate. The process can also include forming a second gate electrode of a second conductivity type lying between the first gate electrode and the channel region, the second conductivity type different from the first conductivity type. The process can further include forming at least a portion of a layer including charge storage material between the first gate electrode and the channel region.

In an embodiment of the third aspect, forming at least a portion of the layer includes forming at least a portion of the layer between the first gate electrode and the second gate electrode. In another embodiment, forming at least a portion of the layer includes forming at least a portion of the layer between the second gate electrode and the channel region.

Note that not all of the activities described above in the general description or the examples are required, that a portion of a specific activity may not be required, and that one or more further activities may be performed in addition to those described. Still further, the order in which activities are listed are not necessarily the order in which they are performed. After reading this specification, skilled artisans will be capable of determining which one or more activities or one or more portions thereof are used or not used and the order of such activities are to be performed for their specific needs or desires.

Any one or more benefits, one or more other advantages, one or more solutions to one or more problems, or any combination thereof have been described above with regard to one or more specific embodiments. However, the benefit(s), advantage(s), solution(s) to problem(s), or any element(s) that may cause any benefit, advantage, or solution to occur or become more pronounced is not to be construed as a critical, required, or essential feature or element of any or all the claims.

The above-disclosed subject matter is to be considered illustrative, and not restrictive, and the appended claims are intended to cover all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. An electronic device including:
a substrate including a channel region; and
a multi-gate electrode structure overlying the channel region, and comprising a first and second gate electrode spaced apart from each other by at least a first portion of first layer having a first dimension along a first imaginary line, wherein the first imaginary line is substantially parallel to a major surface of the substrate;
the first gate electrode of a first conductivity type and having a second dimension along the first imaginary line;
the second gate electrode of a second conductivity type and having a third dimension along the first imaginary line, the second conductivity type different from the first conductivity type; and
a first sidewall structure portion separated from a second sidewall structure portion by a fourth dimension along the first imaginary line, wherein the sum of the first, second, and third dimensions are substantially equal to the fourth dimension.

2. The electronic device of claim 1, wherein the first layer comprises a dielectric material.

3. The electronic device of claim 2 wherein a second portion of the first layer is a gate dielectric between the first gate electrode and the channel region.

4. The electronic device of claim 3 further comprising a gate dielectric between the second gate electrode and the channel region.

5. The electronic device of claim 4 wherein a charge storage material is embedded within the gate dielectric of the first layer.

6. The electronic device of claim 5 wherein the charge storage material further comprises a plurality of discontinuous storage elements.

7. The electronic device of claim 5 wherein the charge storage material comprises a floating gate of the electronic device.

8. The electronic device of claim 4, wherein, the second gate electrode lies between the channel region and a portion of the first gate electrode along a second imaginary line perpendicular to a major surface of the substrate.

9. The electronic device of claim 8 wherein the channel region has the first conductivity type.

10. The electronic device of claim 4, further comprising a charge storage material between the second gate electrode and the channel region.

11. The electronic device of claim 10 wherein the charge storage material further comprises a plurality of discontinuous storage elements.

12. The electronic device of claim 10 wherein the charge storage material is a floating gate of the electronic device.

13. An electronic device including:
a substrate comprising a channel region;
a first gate electrode of a first conductivity type overlying the channel region;
a second gate electrode of a second conductivity type lying between a portion of the first gate electrode and the channel region, the second conductivity type different from the first conductivity type; and
a first portion of a layer comprising a charge storage material lying between the first gate electrode and the substrate.

14. The electronic device of claim 13 wherein a second portion of the layer lies between the first and second gate electrodes.

15. The electronic device of claim 14, wherein the channel region further comprises a channel region of the first conductivity type.

16. The electronic device of claim 13 wherein the layer lies between the second gate electrode and the channel region.

17. The electronic device of claim 16, wherein the channel region further comprises a channel region of the second conductivity type.

18. A process for forming an electronic device comprising:
forming a first gate electrode of a first conductivity type overlying a channel region of a substrate;
forming a second gate electrode of a second conductivity type lying between the first gate electrode and the channel region, the second conductivity type different from the first conductivity type; and
forming at least a portion of a layer comprising charge storage material between the first gate electrode and the channel region.

19. The process of claim 18 wherein forming at least a portion of the layer includes forming at least a portion of the layer between the first gate electrode and the second gate electrode.

20. The process of claim 18 wherein forming at least a portion of the layer includes forming at least a portion of the layer between the second gate electrode and the channel region.
